(19) United States
(12) Patent Application Publication
(10) Pub. No.: US 2020/0292084 A1
(43) Pub. Date: Sep. 17, 2020

(54) GATE VALVE FOR CONTINUOUS TOW PROCESSING

(71) Applicant: APPLIED MATERIALS, INC., Santa Clara, CA (US)

(72) Inventors: Joseph YUDOVSKY, Campbell, CA (US); David ISHIKAWA, Mountain View, CA (US); Travis TESCH, Santa Clara, CA (US)

(21) Appl. No.: 16/306,189

(22) PCT Filed: Jun. 2, 2017
(86) PCT No.: PCT/US2017/035735

§ 371 Date: Nov. 30, 2018

Related U.S. Application Data
(60) Provisional application No. 62/344,970, filed on Jun. 2, 2016.

(51) Int. Cl. F16K 3/02; B08B 5/02; F16K 51/02; H01L 21/67; G05D 16/20

(52) U.S. Cl. CPC F16K 3/029; B08B 5/02; G05D 16/2066; H01L 21/67017; F16K 51/02

(57) ABSTRACT

Embodiments of gate valves and methods for using same are provided herein. In some embodiments, a gate valve for processing a continuous substrate includes: a body; a plurality of seals disposed within the body and configured to move between a closed position and an open position; a plurality of volumes disposed between adjacent ones of the plurality of seals and defined by the plurality of seals and the body; a gas inlet disposed through a first side of the body and fluidly coupled to an innermost one of the plurality of volumes; and a gas outlet disposed through a second side of the body opposite the first side and fluidly coupled to other ones of the plurality of volumes disposed on either side of the innermost one of the plurality of volumes.

### FIELD

Embodiments of the present disclosure generally relate to substrate processing equipment.

### BACKGROUND

Within substrate processing equipment, a gate valve may be utilized, for example, in multi-chamber processing systems to selectively isolate or couple adjacent volumes. For example, current multi-chamber processing apparatus typically include semiconductor processing slit valves and gate valves to isolate pressure controlled processing volumes during transfer of work parts or repair of one or more fluidly connected processing regions. However, the inventors have observed that the seals and sealing surfaces of the conventional valves are limited in their sealing ability, especially if an interfering material such as a continuous substrate is present at the seal interface. Ineffective leak control is especially problematic in multiple processing volumes, when the process in each chamber uses a different pressure, or when only one of the processing volumes needs to be vented and cooled for service or due to emergency process stops.

Accordingly, the inventors have provided an improved gate valve.

### SUMMARY

Embodiments of gate valves and methods for using same are provided herein. In some embodiments, a gate valve includes: a body; a plurality of seals disposed within the body and configured to move between a closed position and an open position; a plurality of volumes defined by the plurality of seals and the body; a gas inlet disposed through a first side of the body and fluidly coupled to an innermost one of the plurality of volumes; and a gas outlet disposed through a second side of the body opposite the first side and fluidly coupled to other ones of the plurality of volumes.

In some embodiments, a gate valve for processing a continuous substrate includes: a body having a first wall, a second wall opposite the first wall, an opening disposed from a first surface to an opposing second surface of the body, wherein the opening is configured to hold and convey a continuous substrate; a plurality of seals movably disposed between the first wall and the second wall, configured to move between a closed position to seal the opening, and an open position that reveals the opening; a plurality of volumes disposed between adjacent ones of the plurality of seals and defined by the plurality of seals and the body; a gas inlet disposed through a first side of the body and fluidly coupled to an innermost one of the plurality of volumes on the first side of the body, wherein the gas inlet fluidly coupled to an innermost one of the plurality of volumes; and a gas outlet disposed through a second side of the body opposite the first side and fluidly coupled to other ones of the plurality of volumes disposed on either side of the innermost one of the plurality of volumes.

In some embodiments, a processing system for processing a continuous substrate includes: a first chamber for processing a continuous substrate; a second chamber for processing the continuous substrate; and a gate valve coupling the first chamber to the second chamber and having an opening through which the continuous substrate can extend between the first chamber and the second chamber, wherein the gate valve is as described in any of the embodiments disclosed herein, and wherein a first side the body is coupled to the first chamber and a second side of the body is coupled to the second chamber.

In some embodiments, a method of processing a continuous substrate includes: processing a continuous substrate in at least one of a first process chamber or a second process chamber coupled to the first process chamber through a gate valve, wherein the continuous substrate is simultaneously disposed through each of the first process chamber, the gate valve, and the second process chamber; and closing the gate valve while the continuous substrate is disposed therethrough to substantially isolate the first process chamber from the second process chamber.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic view of a multiple chamber reactor having a gate valve in accordance with at least some embodiments of the present disclosure.

FIG. 2A depicts a schematic side view of a gate valve in an open position in accordance with at least some embodiments of the present disclosure.

FIG. 2B depicts a schematic side view of the gate valve of FIG. 2A in a closed position in accordance with at least some embodiments of the present disclosure.

FIG. 3A depicts a schematic side view of a gate valve in an open position in accordance with at least some embodiments of the present disclosure.

FIG. 3B depicts a schematic side view of the gate valve of FIG. 3A in a closed position in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of gate valves and methods for using same are provided herein. The disclosed gate valves and methods of using same advantageously benefit vacuum processing of continuous web, film, sheet, ribbon-like fiber and other thin or flat substrates. For some applications, maintaining a continuous substrate, without breaks or joints, across one or more sealing interfaces that correspond to one or more openings where material is transferred into or out of a processing volume is beneficial. Conventional semiconductor processing slit valves and gate valves are used for transferring discrete work parts into pressure controlled processing volumes. These conventional designs, and the seals and sealing surfaces specifically, are limited in their capacity to maintain adequate leak integrity if interfering material is present at the seal interface. For some applications such as chemical vapor infiltration of ceramic fibers, conveying one or more tow across multiple vacuum breaks such that the start of the tow (e.g., an untwisted bundle of continuous filaments) may be at atmospheric pressure, a middle section at reduced pressure, and the end of the tow at atmospheric pressure is advantageous. The foregoing arrangement allows the process to pause and for substrate loading adjustments, or repairs to be made without bringing the furnace to atmospheric pressure. The disclosed gate valve is capable of producing the pressure gradient without compromising the physical integrity of the continuous substrate at the sealing interface. Furthermore, keeping the furnace hot when the processing volumes are not in use is beneficial for system utilization and furnace component reliability.

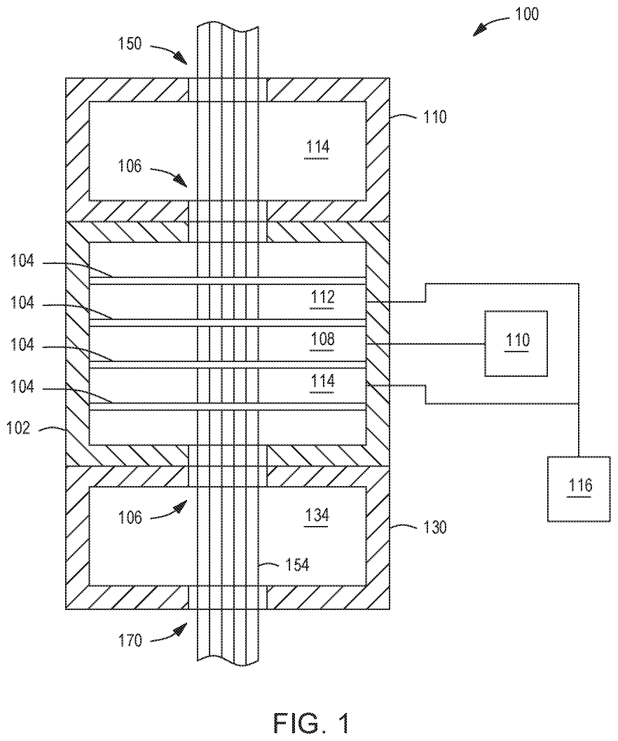

The gate valves of the present disclosure may be used in any application in which a conventional gate valve may be used, for example in applications in which throttling the flow of a gas between two adjacent volumes is desirable or advantageous. In a non-limiting application, the disclosed gate valve may be disposed between chambers in a two process chamber system, or other suitable process chambers that require a gate valve. For example, FIG. 1 depicts a schematic diagram of a two chamber system of the kind that may be used to practice embodiments of the disclosure as discussed herein.

The illustrative two process chamber system 100 includes a first chamber 110 (e.g., a process chamber) having a first chamber volume 114 within a first chamber body (wall 120). In some embodiments, a substrate feedthrough 150 may be provided for conveying a continuous substrate between the first chamber volume 114 and a volume disposed outside of the first chamber 110 (e.g., an adjacent process chamber, a substrate handler, or the like). The system 100 also includes a second chamber 130 (e.g., a process chamber) having a second chamber volume 134 within a second chamber body (wall 140). In some embodiments, a substrate feedthrough 170 may be provided for conveying the continuous substrate between the second chamber volume 134 and a volume disposed outside of the second chamber 130 (e.g., an adjacent process chamber, a substrate handler, or the like). First chamber 110 and second chamber 130 are selectively fluidly coupled to each other via a gate valve 102.

In operation, a continuous substrate 154 is conveyed through substrate feedthroughs 150 and 170, via an opening 106 of the gate valve. The continuous substrate 154 may be processed in the first chamber volume 114 at a first chamber pressure, conveyed to the second chamber volume 134 through the gate valve 102, and processed in the second chamber volume 134 at a second chamber pressure. In some embodiments, the first chamber pressure and the second chamber pressure are the same. In other embodiments, the first chamber pressure and the second chamber pressure are different.

The gate valve 102 is configured to provide selective isolation between the first chamber volume 114 and the second chamber volume 134. For example, isolation between the first chamber volume and the second chamber volume may be desired when one of the chamber volumes needs to be at atmospheric pressure and temperature in order to repair the affected chamber, perform substrate loading adjustments in one of the chambers, or due to an emergency stop. The gate valve 102 includes a plurality of sealing members (four sealing members 104 shown in FIG. 1). In some embodiments, the sealing members may be compliant bladders that can inflate to form a seal, and deflate to open. The sealing members 104 can close while the continuous substrate 154 is disposed through the gate valve without damaging the continuous substrate 154. In some embodiments, a purge gas, such as an inert gas, for example nitrogen (N₂) gas, can be provided to a volume 108 between two of the sealing members 104. In some embodiments, a vacuum, for example from a vacuum source 116, may be provided to one or more volumes between two of the sealing members 104. In some embodiments, the vacuum source 116 is coupled to volumes 112 and 114 disposed on either side of the volume 108 to provide a vacuum in respective volumes on either side of the purge gas provided to the volume 108.

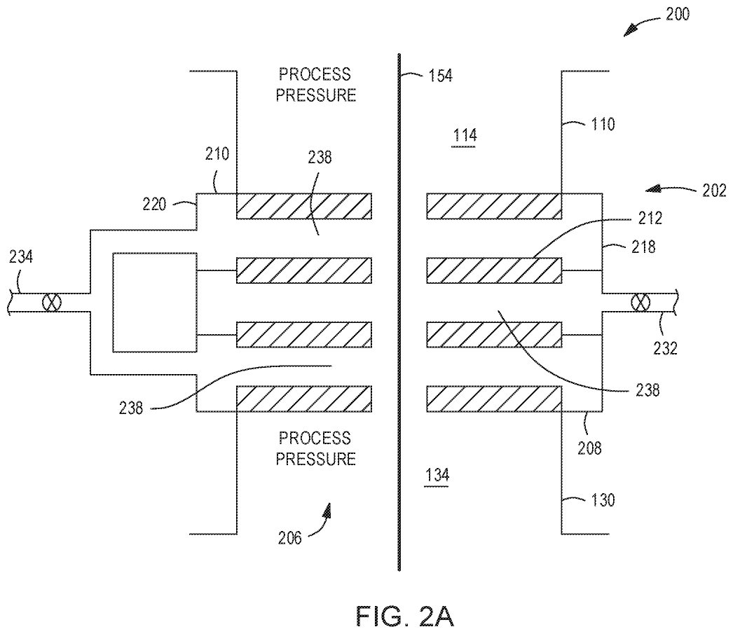

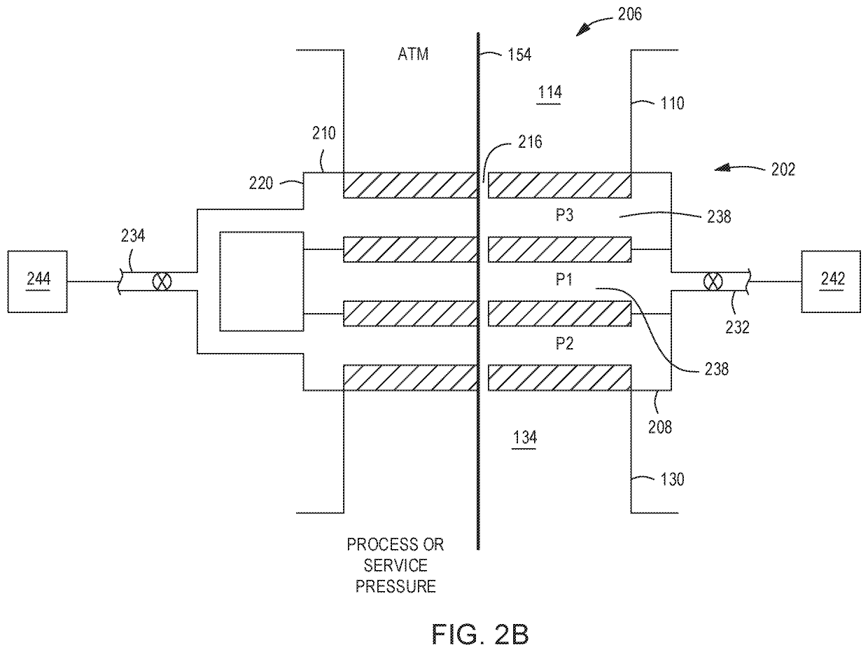

FIGS. 2A and 2B depict a gate valve 200 suitable for use as the gate valve 102 in further detail, and illustrate the gate valve 200 in both open (FIG. 2A) and closed (FIG. 2B) positions. For ease of illustration only, certain elements, such as the purge gas source, valves, and conduits shown in FIG. 2A are omitted from the view in FIG. 2B so as not to clutter the figure.

FIG. 2A depicts a schematic side view of the gate valve 200 in accordance with some embodiments of the present disclosure. The gate valve 200 includes a body 202 having an opening 206 disposed through the body 202 (for example, from a first surface 208 of the body 202 to an opposing second surface 210 of the body 202). The gate valve 200 is coupled to the first chamber 110 (on one side of the opening 206) and to the second chamber 130 (on the other side of the opening 206). The body may also include a first side 218, and a second side 220 opposite the first side 218 which together with the first surface 208 and second surface 210 form a shape of the body. The body 202 may have any suitable shape as required for a particular application, for example, the body 202 may have a suitable shape appropriate for coupling the gate valve 200 to the first and second chambers 110, 130 or to another chamber, as appropriate. The body 202 may be fabricated from one or more process-compatible materials, including non-limiting examples such as stainless steel or aluminum.

The gate valve 200 may further include a plurality of seals 212 disposed between the first surface 208 and the second surface 210 of the body 202 proximate the opening 206. In some embodiments, for example, as depicted in FIGS. 2A and 2B, the plurality of seals are disposed parallel to the first surface 208 and the second surface 210 of the body 202. The plurality of seals 212, for example, may be part of the body 202, or may be welded, bolted, or otherwise affixed to the body 202. The plurality of seals 212 may be fabricated from an elastic or stretchable material, such as rubber bladders. The plurality of seals 212 are disposed within the body, and configured to move between a closed position and an open position. A plurality of volumes 238 is defined by the plurality of seals 212 and the body 202. Each respective volume 238 is disposed between adjacent seals 212. For example, as depicted in FIGS. 2A-B, there are four seals 212, and accordingly three volumes 238.

The gate valve may further include a gas inlet 232 having a valve disposed through the first side 218 of the body and fluidly coupled to an innermost one of the plurality of volumes 238 (e.g., a central one of the volumes 238). The gate valve may also include a gas outlet 234 disposed through the second side 220 of the body and fluidly coupled to other ones of the plurality of volumes 238 disposed on opposite sides of the central volume 238. A purge gas source 242 (shown in FIG. 2B) is coupled to the gas inlet 232 to deliver a purge gas to the innermost one of the plurality of volumes 238. The purge gas may be nitrogen (N₂), although other appropriate process-inert gas, including, as non-limiting examples, helium (He), argon (Ar), or the like, or mixtures of inert gases, may be used as the purge gas. A vacuum pump 244, for example, a turbo pump or the like, is fluidly coupled to the gas outlet 234.

In operation, a continuous substrate 154 may be processed in the first and second chamber volumes 114, 134, as discussed above. As depicted in FIG. 2A, in the open position of the gate valve 200, the gas inlet 232 coupled to the purge gas source 242, and the gas outlet 234 coupled to the vacuum pump 244 are closed, and the first chamber pressure is the same as the second chamber pressure, as the continuous substrate is processed. In the event that the first chamber pressure is required to be different from the second chamber pressure, for example for substrate loading adjustments or repairs, the gate valve 200 is moved to the closed position facilitating establishment of a pressure difference between the first chamber and the second chamber. The purge gas source 242 and vacuum pump 244 are not shown in FIG. 2A for clarity.

As depicted in FIG. 2B, in the closed position, the plurality of seals 212 partially seal the opening 206 and create a corresponding plurality of small leaks 216 along the opening 206. As depicted in FIG. 2B, in the closed position of the gate valve 200, the gas inlet 232 coupled to the purge gas source 242, and the gas outlet 234 coupled to the vacuum pump 244 may be opened, such that the innermost one of the plurality of volumes 238 stays at a pressure P1 different from the other ones of the plurality of volumes 238 (e.g., P2 and P3). For example, the innermost one of the plurality of volumes 238 may be maintained at a pressure a higher than the other ones of the plurality of volumes 238 due to the flow of the purge gas from purge gas source 242. Any purge gas escaping through the leaks 216 may be carried away via the vacuum pump 244. As such, if for example, one chamber is undergoing repairs, performed at atmospheric pressure, the non-affected chamber may remain at a processing pressure, different from the pressure at atmospheric conditions, such as lower than atmospheric pressure. Thus, the pressure difference is maintained or substantially maintained, and the repair of one of the chambers is completed without bringing the whole system to atmospheric pressure. Also, the disclosed gate valve produces the desired pressure gradient without compromising the physical integrity of a continuous substrate at the sealing interface, when present.

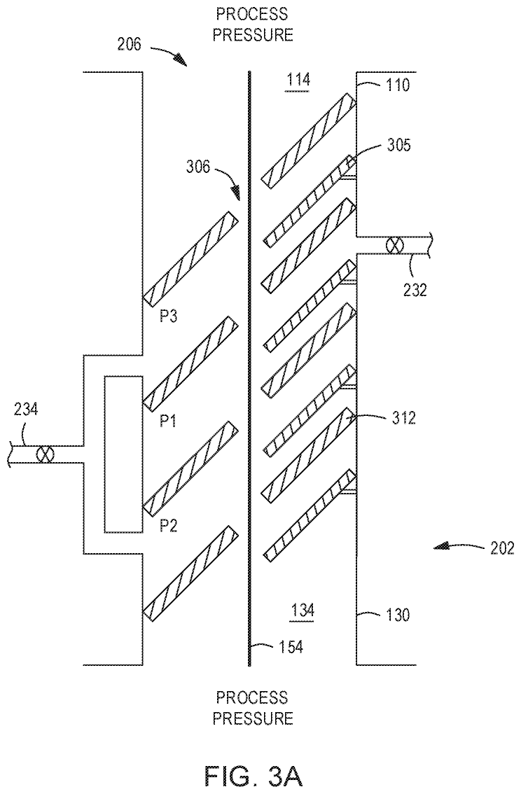

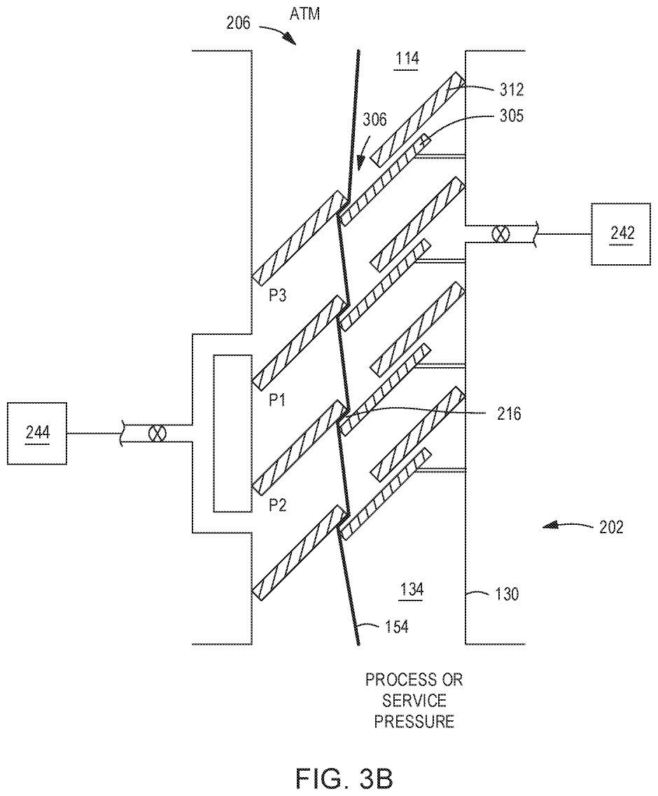

FIG. 3A-3B respectively depict a schematic side view of a gate valve in an open and a closed position in accordance with at least some embodiments of the present disclosure. As depicted in FIG. 3A-3B, in some embodiments, the plurality of seals may be provided by a plurality of angled walls 312 having respective openings 306 that can be selectively sealed via movable sealing members 305. For example, the sealing members 305 may operate similar to slit valves disposed below each one of the plurality of angled walls 312, and configured to move between a first position (e.g., an open position as depicted in FIG. 3A) and a second position (e.g., a closed position as depicted in FIG. 3B).

Each sealing member 305 may be independently controlled to provide individualized flow conditions (e.g., individualized control of mass flow, volume flow, pressure, etc.) to each one of the other ones of the plurality of volumes 238. Accordingly, in some embodiments, mass flow controllers, volume flow controllers, or pressure regulators may be coupled to the volumes disposed between the angled walls 312.

In some embodiments, sealing members 305 are pneumatically controlled between at least the first position in which the valve is fully open and the second position in which the valve is fully closed. In some embodiments, the sealing members 305 may be controlled by other mechanisms, for example servo motors. In the exemplary open position depicted on FIG. 3A, the sealing members 305 are in the first position and the gate valve is fully open to maintain a common pressure between the first chamber 110 and the second chamber 130 (as depicted in FIG. 1). The purge gas source 242 and vacuum pump 244 are shown only in FIG. 3B for clarity.

In the exemplary closed position, depicted in FIG. 3B, the sealing members 305 partially seal the opening 206 and create a corresponding plurality of leaks 216 along the opening 206. The plurality of seals 212 and sealing members 305 are advantageously tilted to enhance gas flow and maintain a desired pressure gradient. The amount of tilt depends on the vertical offset between the gas inlet 232 and the gas outlet 234. As depicted in FIGS. 3A and 3B, the gas outlet 234 is disposed at a height below the gas inlet 232.

In the exemplary closed position depicted in FIG. 3B, the plurality of sealing members 305 move from the first position to the second position in a direction counter to the tilt angle to engage the plurality of seals 212 and seal the opening 206. Similar to the illustrative embodiment in FIG. 2B, a corresponding plurality of leaks 216 along the opening 206 is created. Similar to the illustrative embodiment in FIG. 2B, the gas inlet 232 coupled to the purge gas source 242 and the gas outlet 234 coupled to the vacuum pump 244 are open, such that the innermost one of the plurality of volumes 238 can be maintained at a pressure different from the other ones of the plurality of volumes 238. For example, the innermost one of the plurality of volumes 238 may be maintained at a pressure a higher than the other ones of the plurality of volumes 238 due to the flow of the purge gas from purge gas source 242. Similarly, the inventive gate valve including sealing members 305 advantageously produces a pressure gradient without compromising the physical integrity of a continuous substrate at the sealing interface.

In operation, a method of processing a continuous substrate using the above disclosed apparatus includes processing a continuous substrate in at least one of a first process chamber or a second process chamber coupled to the first process chamber through a gate valve. The continuous substrate is simultaneously disposed through each of the first process chamber, the gate valve, and the second process chamber. The gate valve can be closed while the continuous substrate is disposed therethrough to substantially isolate the first process chamber from the second process chamber. In some embodiments, the first process chamber is maintained at a vacuum pressure and a pressure of the second process chamber can be increased while substantially maintaining the pressure in the first process chamber. In some embodiments, the pressure of the second process chamber can be increased to substantially atmospheric pressure while substantially maintaining the pressure in the first process chamber. In some embodiments, service can be performed on the second process chamber while substantially maintaining the pressure in the first process chamber.

Thus, embodiments of improved gate valves and methods of using the same have been provided herein. The inventive gate valves and methods of using may advantageously ensure that a non-affected chamber of a system of chambers may remain at a processing pressure, different from, for example the atmospheric conditions required for the affected chambers.

While the foregoing is directed to embodiments of the present disclosure, other and further embodiments of the disclosure may be devised without departing from the basic scope thereof.

1. A gate valve for processing a continuous substrate, comprising:
a body;
a plurality of seals disposed within the body and configured to move between a closed position and an open position;
a plurality of volumes disposed between adjacent ones of the plurality of seals and defined by the plurality of seals and the body;
a gas inlet disposed through a first side of the body and fluidly coupled to an innermost one of the plurality of volumes; and
a gas outlet disposed through a second side of the body opposite the first side and fluidly coupled to other ones of the plurality of volumes disposed on either side of the innermost one of the plurality of volumes.

2. The gate valve of claim 1, wherein the plurality of seals is four seals.

3. The gate valve of claim 1, wherein the plurality of seals comprise rubber bladders.

4. The gate valve of claim 1, wherein the plurality of seals each comprise angled walls having respective openings that can be selectively sealed via movable sealing members.

5. The gate valve of claim 1, further comprising a first valve disposed in the gas inlet.

6. The gate valve of claim 5, further comprising a purge gas source coupled to the gas inlet.

7. The gate valve of any of claims 1 to 6, further comprising a second valve disposed in the gas outlet.

8. The gate valve of claim 7, further comprising a vacuum source coupled to the gas outlet.

9. A processing system for processing a continuous substrate, comprising:
a first chamber for processing a continuous substrate;
a second chamber for processing the continuous substrate; and
a gate valve coupling the first chamber to the second chamber and having an opening through which the continuous substrate can extend between the first chamber and the second chamber, wherein the gate valve is as described in any of the preceding claims, and wherein a first side the body is coupled to the first chamber and a second side of the body is coupled to the second chamber.

10. The processing system of claim 9, further comprising:
a purge gas source coupled to the gas inlet; and
a vacuum source coupled to the gas outlet.

11. A method of processing a continuous substrate, comprising:
processing a continuous substrate in at least one of a first process chamber or a second process chamber coupled to the first process chamber through a gate valve, wherein the continuous substrate is simultaneously disposed through each of the first process chamber, the gate valve, and the second process chamber; and
closing the gate valve while the continuous substrate is disposed therethrough to substantially isolate the first process chamber from the second process chamber.

12. The method of claim 11, wherein the first process chamber is maintained at a vacuum pressure and further comprising:
increasing a pressure of the second process chamber while substantially maintaining the pressure in the first process chamber.

13. The method of claim 12, wherein the pressure of the second process chamber is substantially atmospheric pressure.

14. The method of claim 11, further comprising:
performing service on the second process chamber while substantially maintaining the pressure in the first process chamber.
